(19) United States
(12) Patent Application Publication
(10) Pub. No.: US 2025/0007025 A1
(43) Pub. Date: Jan. 2, 2025

(54) RECOVERY METHOD OF VALUABLE METAL IN POSITIVE ELECTRODE SHEET OF LITHIUM BATTERY

(71) Applicants: GUANGDONG BRUNP RECYCLING TECHNOLOGY CO., LTD., Foshan, Guangdong (CN); HUNAN BRUNP RECYCLING TECHNOLOGY CO., LTD., Changsha, Hunan (CN); HUNAN BRUNP EV RECYCLING CO., LTD., Changsha, Hunan (CN)

(72) Inventors: Shibao Ouyang, Foshan, Guangdong (CN); Changdong Li, Foshan, Guangdong (CN); Ruokui Chen, Foshan, Guangdong (CN); Xiongcong Fu, Foshan, Guangdong (CN); Dingshan Ruan, Foshan, Guangdong (CN); Yong Cai, Foshan, Guangdong (CN)

(21) Appl. No.: 18/711,231

(22) PCT Filed: Aug. 30, 2022
(86) PCT No.: PCT/CN2022/115955

§ 371 Date: May 17, 2024

(30) Foreign Application Priority Data
Nov. 26, 2021 (CN) 202111420708.9

(51) Int. Cl. H01M 10/54; C01D 15/08; C22B 1/02; C22B 3/22; C22B 3/44; C22B 7/00

(52) U.S. Cl. CPC H01M 10/54; C01D 15/08; C22B 1/02; C22B 3/22; C22B 3/44; C22B 7/007

(57) ABSTRACT

A method for recycling valuable metal in a lithium battery positive plate is provided, comprising the following steps: S1, mixing a positive plate material with reducing metal, and then roasting, the roasting being carried out in a protective atmosphere; S2, performing magnetic separation on the material obtained in step S1 to obtain a magnetic component and a non-magnetic component; S3, performing acid dissolution on the magnetic component, concentrating the obtained leaching solution, and then performing cooling crystallization to obtain a metal salt A; and S4, performing water soaking on the non-magnetic component to obtain sediment and water soaking liquid, adding carbonate into the water soaking liquid to obtain lithium carbonate, performing acid dissolution on the sediment, purifying, and performing evaporative crystallization to obtain a dissolved solution to obtain a metal salt B.

### TECHNICAL FIELD

The present disclosure belongs to the technical field of recycling solid waste, and specifically relates to a recovery method of valuable metal in positive electrode sheet of a lithium battery.

### BACKGROUND

Due to the advantages of light weight and high energy density, lithium batteries have been widely used in fields such as digital electronic products, new energy vehicles and energy storage. In recent years, the vigorous development of the new energy industry has driven the demand for lithium batteries in the consumer market. According to statistics, in 2020, the annual output of pure electric vehicles in Chinese mainland exceeded 2 million, and the cumulative production and sales volume reached 5 million. However, since the service life of lithium batteries is 5˜8 years, with the booming of new energy industry, the waste batteries generated by scrapped products also reached 500,000 tons per year.

Waste lithium-ion batteries contain metal resources such as lithium, nickel, cobalt, manganese, iron, copper, and aluminum, as well as solid and liquid organics. If they are discarded at will, not only are resources wasted, but also are the environment polluted. Therefore, it is necessary to recycling waste lithium-ion batteries.

Traditional recycling of lithium batteries mainly includes two processes: pyrometallurgy and hydrometallurgy. The pyrometallurgy process is to first melt waste lithium batteries into alloys at a high temperature, and then leach and recover valuable metals in the obtained alloys. However, due to the high energy consumption, this process is less used. The hydrometallurgy recovery process mainly includes the following steps in sequence: discharging, disassembling, shredding, sorting, and screening of waste lithium batteries to obtain battery powder and by-products (copper-aluminum residue, diaphragm, etc.), and the battery powder is subjected to leaching, impurity removal, extraction and back-extraction processes to obtain a sulfate solution of nickel, cobalt and manganese, thereby realizing the recycling of valuable metals such as nickel, cobalt, and manganese.

However, the existing hydrometallurgy recovery process of waste lithium batteries has the problems of complicated process and long procedure. In addition, the extraction process also leads to problems such as large occupied area, high investment cost, and difficulty in treatment of organic wastewater.

### SUMMARY

The present disclosure aims to solve at least one of the above-mentioned technical problems existing in prior art. To this end, the present disclosure proposes a recovery method of valuable metal in positive electrode sheet of a lithium battery, which can achieve the purpose of omitting extraction and subsidiary steps thereof through simple impurity removal and separation procedures, simplifying the technological process and saving investment cost.

According to one aspect of the present disclosure, a recovery method of valuable metal in positive electrode sheet of a lithium battery is proposed, comprising steps of:
S1. mixing a material of the positive electrode sheet with a reducing metal to obtain a mixture, and calcinating the mixture, wherein the calcinating is carried out under a protective atmosphere;
S2. performing magnetic separation on a material obtained in step S1 to obtain a magnetic component and a non-magnetic component;
S3. dissolving the magnetic component in an acid, concentrating an obtained leachate, and performing crystallization to obtain a metal salt A; and
S4. leaching the non-magnetic component with water to obtain a sediment and a leachate obtained by water leaching;
adding a carbonate into the leachate obtained by water leaching to obtain lithium carbonate;
dissolving the sediment in an acid, purifying, and then performing crystallization to obtain a metal salt B from an obtained solution after the dissolving.

The reaction mechanism of the recovery method proposed by the present disclosure is as follows.

In step S1, under the calcinating condition, a transition metal compound in the material of the positive electrode sheet is reduced by the reducing metal to an elementary substance of the metal. Combining with the transition metal material commonly used in a material of the positive electrode, it can be known that at least one of elementary substances of nickel, cobalt, and manganese is expected to be generated.

Among them, nickel and cobalt are ferromagnetic, while manganese and other impurities are not ferromagnetic.

In step S2, through magnetic separation, the material obtained in step S1 can be divided into two parts. One part is a magnetic component, which may include at least one of elementary substances of nickel and cobalt, and the other part is a non-magnetic component, which may contain elementary substance of manganese and other impurities.

Step S3 is a conventional process of leaching and crystallization. Since the magnetic component hardly contains impurities, the metal salt A (which may be at least one of nickel salt and cobalt salt) can be obtained by crystallization without an additional impurity removal step.

In step S4, since the lithium compound is almost completely soluble in water, it can be extracted by leaching with water.

A metal component in the sediment can be leached out by subsequent dissolution in the acid, mainly including manganese and other metal impurities. Therefore, it takes a purification step and recrystallization to obtain a metal salt (mainly manganese salt).

According to a preferred embodiment of the present disclosure, it has at least the following beneficial effects.

(1) In step S1 of the present disclosure, the transition metal in the material of the positive electrode sheet is reduced to elementary substance through reductive calcinating, so there is no need to add a reductant in the subsequent leaching (dissolving in an acid) process, leading to milder leaching conditions and higher leaching efficiency.

(2) In the present disclosure, through the reductive calcinating in step S1, the magnetic separation in step S2, and the purification in step S4, the transition metal can be simply recovered from the positive electrode material, and the extraction and subsequent back-extraction steps that must be used in the traditional hydrometallurgy process are omitted, which significantly shorten the recycling process and improve the efficiency of recycling the transition metal.

(3) The present disclosure utilizes the property of co-crystallization of nickel sulfate and cobalt sulfate to directly concentrate the leachate obtained in step S3 and perform cooling crystallization, to obtain high-purity nickel-cobalt binary sulfate crystal, which can be used for subsequent synthesis of precursor material, shortening the recycling process and improving the efficiency of recycling metals.

(4) After the calcinating in step S1, the lithium in the material of the positive electrode sheet is converted into lithium oxide. After adding water for slurrying, the lithium oxide can be leached out, while other substances are insoluble, so that the purpose of selective lithium extraction is achieved. In step S4, lithium is first extracted to avoid loss of lithium in the subsequent purification process.

(5) In summary, with the advantages of simple operation, low production cost, stability and reliability, the recovery method provided by the present disclosure is suitable for industrial production, and results in high recovery rates of lithium, nickel, cobalt and manganese metals, showing extremely high production benefits.

In some embodiments of the present disclosure, with regard to the recovery method, steps S3 to S4 may be interchanged, or may be performed simultaneously.

In some embodiments of the present disclosure, in step S1, the material of the positive electrode sheet comprises at least one of lithium nickel-cobalt manganate, lithium nickelate, lithium cobaltate, lithium manganate, and lithium nickel-cobalt aluminate.

In some preferred embodiments of the present disclosure, in step S1, the material of the positive electrode sheet comprises lithium nickel-cobalt manganate.

In some preferred embodiments of the present disclosure, in step S1, the material of the positive electrode sheet is derived from at least one of lithium-ion batteries (cycled or not cycled), lithium metal batteries (cycled or not cycled) and scrapped positive electrode active powder (homogenized or unhomogenized).

In some embodiments of the present disclosure, in step S1, a form of the material of the positive electrode sheet is at least one of sheet, block, and powder.

Since the powder can improve contact between materials, in some preferred embodiments of the present disclosure, in step S1, the form of the material of the positive electrode sheet is powder.

In some embodiments of the present disclosure, the method for obtaining the powdery material of the positive electrode sheet comprises the processes of shredding, sorting and screening the positive electrode sheet of a lithium battery in sequence.

In some embodiments of the present disclosure, in step S1, the reducing metal comprises at least one of magnesium and aluminum.

In some embodiments of the present disclosure, in step S1, a mass ratio of the reducing metal to the material of the positive electrode sheet is 0.4˜1.2:1.

In some preferred embodiments of the present disclosure, in step S1, the mass ratio of the reducing metal to the material of the positive electrode sheet is 0.5˜1.2:1.

In some preferred embodiments of the present disclosure, in step S1, the mass ratio of the reducing metal to the material of the positive electrode sheet is 0.4˜1.0:1.

In some embodiments of the present disclosure, in step S1, a temperature of the calcinating is 300˜600° C.

In some preferred embodiments of the present disclosure, in step S1, the temperature of the calcinating is 400˜600° C.

In some embodiments of the present disclosure, in step S1, a duration of the calcinating is 2˜5 h.

In some preferred embodiments of the present disclosure, in step S1, the duration of the calcinating is 2˜4 h.

In some embodiments of the present disclosure, in step S1, a heating rate of the calcinating is 1˜5° C./min.

In some embodiments of the present disclosure, in step S1, a starting point for heating of the calcinating is room temperature (10˜40° C.).

In some embodiments of the present disclosure, in step S1, the protective atmosphere comprises at least one of nitrogen, helium and argon.

In some embodiments of the present disclosure, in step S2, a magnetic field strength of the magnetic separation is 10˜30 T.

In some embodiments of the present disclosure, in step S2, the non-magnetic component comprises at least one of the reducing metal, lithium compound and elementary substance of manganese.

In some embodiments of the present disclosure, step S3, before dissolving in the acid, further comprises slurrying the magnetic component by mixing it with water.

In some embodiments of the present disclosure, with regard to the slurrying by mixing, a ratio of the magnetic component to water is 1 g:3˜5 mL.

In some embodiments of the present disclosure, in step S3, the acid used for dissolving in the acid is sulfuric acid.

In some embodiments of the present disclosure, in step S3, with regard to dissolving in an acid, a molar ratio of hydrogen ions in the acid to the magnetic component is 2.2˜3:1.

In the process of dissolving in an acid, a reaction that occurs is shown in the following formula:
M+2H⁺→M²⁺+H₂↑, where M represents a transition metal in the magnetic component, and M²⁺ represents a cation of the transition metal with a valence of +2 generated after being dissolved in the acid.

According to the above formula, a theoretical molar ratio of hydrogen ions in the acid to the magnetic component is 2:1. The ratio of 2.2˜3:1 in the present disclosure actually results in a slight excess of the acid to ensure that the magnetic component is completely dissolved.

In some embodiments of the present disclosure, in step S3, pH of the leachate is 4˜6.

In some preferred embodiments of the present disclosure, in step S3, the pH of the leachate is 4˜5.5.

In some embodiments of the present disclosure, a reagent for adjusting the pH of the leachate is a sodium carbonate solution.

In some embodiments of the present disclosure, in step S3, after the concentrating, a total concentration of the metal in the leachate is 120˜220 g/L.

In some preferred embodiments of the present disclosure, in step S3, after the concentrating, the total concentration of the metal in the leachate is 150˜220 g/L.

In some embodiments of the present disclosure, in step S3, a method of the concentrating is heating and evaporation.

In some embodiments of the present disclosure, in step S3, the crystallization is at least one of cooling crystallization and evaporative crystallization.

In some embodiments of the present disclosure, a temperature of the cooling crystallization is 30˜55° C.

In some embodiments of the present disclosure, a duration of the cooling crystallization is 5˜24 h.

In some preferred embodiments of the present disclosure, the duration of the cooling crystallization is 5˜16 h.

In some embodiments of the present disclosure, the cooling crystallization is performed in a crystallization kettle.

In some embodiments of the present disclosure, the method further comprises performing solid-liquid separation after the cooling crystallization to obtain a crystallized product of the metal salt A.

In some embodiments of the present disclosure, the metal salt A comprises at least one of nickel sulfate and cobalt sulfate.

In some embodiments of the present disclosure, in step S4, with regard to leaching with water, a ratio of the non-magnetic component to water is 1 g:3˜5 mL.

In some embodiments of the present disclosure, in step S4, pH for leaching with water is 6.0˜8.0.

In some embodiments of the present disclosure, a reagent for adjusting the pH for leaching with water is at least one selected from a group consisting of an aqueous sulfuric acid solution, an aqueous solution of an aluminum salt, and an aqueous solution of an iron salt.

The aqueous sulfuric acid solution can provide hydrogen ions to reduce the pH of a water leaching system.

In some embodiments of the present disclosure, a concentration of the aqueous sulfuric acid solution is 2˜6 wt %.

In some embodiments of the present disclosure, when adjusting the pH for leaching with water, a feeding rate of the aqueous sulfuric acid solution is 1.0˜2.5 mL/min.

In the aqueous solution of the aluminum salt and the aqueous solution of the iron salt, metal ions (Al³⁺ and Fe³⁺) will undergo a hydrolysis reaction to combine with hydroxyl radical in water, thereby increasing a proportion of hydrogen ions in the system, and reducing the pH of the water leaching system.

In some embodiments of the present disclosure, the aluminum salt is at least one of aluminum sulfate, aluminum nitrate, and aluminum chloride.

In some embodiments of the present disclosure, a concentration of the aqueous solution of the aluminum salt is 10˜15 wt %.

In some embodiments of the present disclosure, a concentration of the aqueous solution of the iron salt is 10˜15 wt %.

In some embodiments of the present disclosure, the iron salt is at least one of ferric sulfate, ferric nitrate and ferric chloride.

In some embodiments of the present disclosure, when adjusting the pH for leaching with water, a feeding rate of the aqueous solution of the aluminum salt or the aqueous solution of the iron salt is 2.0˜5.0 mL/min.

In some embodiments of the present disclosure, a reagent for adjusting the pH for leaching with water is pumped into the water leaching system by using a peristaltic pump.

In some embodiments of the present disclosure, step S4 further comprises washing the sediment for 2˜3 times, and a generated washing solution is combined with the leachate obtained by water leaching to be used for preparing the lithium carbonate.

The aluminum salt and the iron salt will undergo a hydrolysis reaction in the aqueous solution to generate corresponding ferric hydroxide and aluminum hydroxide, and when the pH is 6˜8, the ferric hydroxide and the aluminum hydroxide are insoluble in water. Therefore, the introduced aluminum and iron impurities can be removed by simple solid-liquid separation.

In some embodiments of the present disclosure, in step S4, the carbonate comprises sodium carbonate.

In some embodiments of the present disclosure, step S4 further comprises slurrying at a ratio of the sediment:water=1 g:3˜5 mL before dissolving in the acid.

In some embodiments of the present disclosure, in step S4, pH for dissolving in the acid is 1.0˜1.5.

In some embodiments of the present disclosure, in step S4, a reagent for adjusting the pH of the acid dissolving system is sulfuric acid.

In some embodiments of the present disclosure, in step S4, a temperature for dissolving in the acid is 60˜80° C.

In some embodiments of the present disclosure, in step S4, a duration for dissolving in the acid is 2˜4 h.

In some embodiments of the present disclosure, in step S4, the purification comprises adjusting the pH of the acid dissolving system to 4.0˜5.0 to remove aluminum; and a pH adjusting agent used is sodium carbonate.

In some embodiments of the present disclosure, the aluminum removal comprises adjusting the pH to 4.0˜5.0 and then performing solid-liquid separation to obtain aluminum residue and a first solution after the dissolving.

In some embodiments of the present disclosure, the aluminum removal further comprises washing the aluminum residue for 2˜3 times, and mixing an obtained washing solution with the first solution after the dissolving.

In some embodiments of the present disclosure, the recovery method further comprises preparing elementary substance of aluminum from the aluminum residue, comprising steps of:

D1. adding pure water to the aluminum residue for slurrying, adjusting pH to 12˜14 for reaction, and filtering;

D2. adjusting pH of a filtrate obtained in step S1 to 6.0˜8.0, and then filtering to obtain filter residue;

D3. calcinating the filter residue obtained in step D2 to obtain alumina; and

D4. electrolyzing the alumina at a temperature of 900˜1000° C. by using the alumina as a solute, cryolite (sodium hexafluoroaluminate, molten) as a solvent, graphite as anode, and aluminum liquid as cathode to obtain the elementary substance of aluminum.

In some embodiments of the present disclosure, in step D1, a reagent for adjusting the pH is 20˜30 wt % of sodium hydroxide solution.

In some embodiments of the present disclosure, in step D1, a temperature of the reaction is 80˜95° C.

In some embodiments of the present disclosure, in step D1, a duration of the reaction is 40˜60 min.

In some embodiments of the present disclosure, in step D2, a reagent for adjusting the pH is sulfuric acid.

In some embodiments of the present disclosure, in step D3, a temperature of the calcinating is 400˜600° C.

In some embodiments of the present disclosure, in step D3, a duration of the calcinating is 2˜5 h.

In some embodiments of the present disclosure, in step D3, an atmosphere of the calcinating is air.

In the present disclosure, the aluminum residue obtained after aluminum removal can be electrolyzed to obtain elementary substance of aluminum, through which not only the aluminum foil in the electrode sheet is recovered, but also the added aluminum powder can be recovered, thereby realizing the recycling of aluminum and improving the economic viability of the recovery method.

In some embodiments of the present disclosure, the purification further comprises performing magnesium removal treatment on the obtained first solution after the dissolving after the aluminum removal.

In some embodiments of the present disclosure, a reagent used in the magnesium removal is selected from sodium fluoride.

In some embodiments of the present disclosure, the magnesium removal further comprises performing a solid-liquid separation treatment after adding the sodium fluoride to obtain magnesium residue and a second solution after the dissolving.

In some embodiments of the present disclosure, the magnesium removal further comprises washing the magnesium residue for 2˜3 times with water, and mixing the obtained washing solution with the second solution after the dissolving to obtain solution after the dissolving.

In some embodiments of the present disclosure, a method for the crystallization in step S4 comprises at least one of cooling crystallization and evaporative crystallization.

In some embodiments of the present disclosure, a method for the crystallization in step S4 and a method for the crystallization in step S3 may be the same or different.

In some preferred embodiments of the present disclosure, a method for the crystallization in step S4 is evaporative crystallization.

In some embodiments of the present disclosure, the metal salt B comprises manganese sulfate.

In some embodiments of the present disclosure, the recovery method further comprises preparing a precursor of a positive electrode material by using the metal salt A and the metal salt B.

In some embodiments of the present disclosure, a preparation method for the precursor of the positive electrode material comprises dissolving the metal salt A and the metal salt B with pure water, adjusting a molar ratio of nickel, to cobalt, and to manganese in the system to a target ratio, then adding ammonia water and sodium hydroxide, adjusting the pH of the solution, and controlling the synthesis reaction temperature for co-precipitation reaction, and then filtering, washing, drying and screening the obtained solid.

### BRIEF DESCRIPTION OF DRAWINGS

The present disclosure will be further described below in conjunction with the accompanying drawings and examples, in which:

FIG. 1 is a schematic diagram of the reaction scheme of Example 1 of the present disclosure.

### DETAILED DESCRIPTION OF EMBODIMENTS

The concept of the present disclosure and the technical effects produced thereby will be clearly and completely described below in conjunction with examples, so as to fully understand the purpose, features and effects of the present disclosure. Apparently, the described examples are only a part of examples of the present disclosure, rather than all examples. Based on examples of the present disclosure, other examples obtained by those skilled in the art without creative efforts are all within the scope of protection of the present disclosure.

### Example 1

This example provided a recovery method of valuable metal in positive electrode sheet of a lithium battery, and the specific process was as follows:

A1. Pretreatment: A waste ternary positive electrode sheet of a lithium battery (from Guangdong Brunp Recycling Technology Co., Ltd., containing Ni 47.3%, Co 6.2%, Mn 5.9%, and Li 7.2% in terms of mass percentage) was subjected to shredding, sorting and screening processes in sequence to obtain electrode sheet powder.

A2. Deep reduction of aluminum powder:

A21. The electrode sheet powder obtained in step A1 was mixed uniformly with aluminum powder at a mass ratio of 1:0.5; and
A22. The powder obtained in step A21 was placed in a tube furnace under a nitrogen atmosphere, heated at a heating rate of 1° C./min, from 25° C. to 400° C., then calcinated for 4 h and cooled.
A3. Magnetic separation: The electrode sheet powder obtained in step A2 was subjected to magnetic separation with a magnetic separator under the condition of a magnetic field strength of 10 T to obtain magnetic powder of elementary substances of nickel and cobalt (magnetic components) and non-magnetic mixed material including manganese, lithium (compound), aluminum (compound+elementary substance) and the like (non-magnetic components).

A4. Preparation of nickel-cobalt binary sulfate crystal:
A41. The magnetic components obtained in step A3 were added with pure water at a solid-liquid ratio of 1 g:3 mL for slurrying;
A42. The slurry obtained in step A41 was added with sulfuric acid for acid dissolution, wherein a molar ratio of sulfuric acid to the magnetic components was 1.1:1;
A43. After the magnetic components were completely dissolved, a sodium carbonate solution was added to the obtained nickel-cobalt solution to adjust the pH to 5.0; and
A44. The pH-adjusted nickel-cobalt solution was evaporated to concentrate the total concentration of nickel and cobalt to 150 g/L, then the concentrated solution was transferred to a crystallization kettle for cooling crystallization at 55° C. for 16 h, followed by centrifugation treatment, to obtain high-purity nickel-cobalt binary sulfate crystal.

After detection, the recovery rate of nickel and cobalt was 99.5%. The recovery rate was calculated by the product of a mass of the nickel-cobalt binary sulfate crystal and a mass content of nickel and cobalt in the nickel-cobalt binary sulfate crystal, divided by a mass of the electrode sheet powder in step A1, and then divided by a mass content of nickel and cobalt in the electrode sheet powder, wherein the method for determining the mass content of nickel and cobalt was ICP-OES; meanwhile, the mother liquor after crystallization can be recycled, and the calculation here was the overall result after multiple cycles, that is, the overall recovery rate of nickel and cobalt.

A5. Selective lithium extraction:
A51. The non-magnetic components obtained in step A3 were added with pure water at a solid-liquid ratio of 1 g:3 mL for slurrying;
A52. Under stirring, a sulfuric acid solution with a concentration of 6 wt % was injected with peristaltic pump at flow rate of 1 mL/min, to adjust the pH of the slurry obtained in step A51 to 6.0, after that, stirring was continued for 30 min and filtration was performed to obtain filter residue and an extract by means of water;
A53. The filter residue obtained in step A52 was washed with pure water, and a washing solution obtained was added to the extract by means of water,
the specific operation of washing was as follows: firstly, pure water was added to the filter residue at a solid-liquid ratio of 1 g:3 mL for slurrying, and stirred for 30 min, then, the filter residue and the washing solution were obtained by filtration, and then the obtained filter residue was rinsed with pure water twice; and
A54. Sodium carbonate was added to the extract by means of water obtained in step A53 to prepare battery-grade lithium carbonate;

A6. Preparation of manganese sulfate crystal:
A61. The filter residue obtained in step A53 was added with pure water at a solid-liquid ratio of 1 g:3 mL for slurrying;
A62. Under stirring, the slurry obtained in step A61 was added with sulfuric acid to adjust the pH to 1.0, and reacted at 80° C. for 2 h;
A63. The slurry obtained in step A62 was added with a sodium carbonate solution to adjust the pH of the slurry to 5.5, and filtration was performed to obtain aluminum residue and a manganese sulfate solution;
the aluminum residue was washed twice with pure water, and the washing solution was combined into the manganese sulfate solution; and
A64. The manganese sulfate solution obtained in step A63 was subjected to evaporative crystallization to prepare battery-grade manganese sulfate crystal.

A7. Preparation of elementary substance of aluminum from aluminum residue:
A71. The aluminum residue obtained in step A63 was added with pure water for slurrying with a solid-liquid ratio of 1 g:3 mL;
A72. The slurry obtained in step A71 was added with 20 wt % of sodium hydroxide solution and stirred at 80° C. for 60 min, with the pH at end point of the reaction adjusted to 14, and filtration was performed;
A73. The solution obtained in step A72 was added with sulfuric acid to adjust pH to 6.0, and then filtered to obtain filter residue;
A74. The filter residue obtained in step A73 was calcinated at 400° C. for 5 h in a tube furnace under an air atmosphere to obtain alumina; and
A75. The alumina was electrolyzed at a temperature of 950° C. with direct current by using the alumina obtained in step A74 as a solute, cryolite as a solvent, graphite as anode, and aluminum liquid as cathode to obtain elementary substance of aluminum.

A8. Precursor synthesis:

The nickel-cobalt binary sulfate crystal obtained in step A4 and the manganese sulfate crystal obtained in step A6 were dissolved with pure water, and a molar ratio of nickel, to cobalt, and to manganese in the system was adjusted to 5:2:3. Then, ammonia water and sodium hydroxide were added to adjust the pH of the solution to 11.0, and the synthesis reaction temperature was controlled to 65° C. After the reaction was complete, a precursor material of NCM 5:2:3 type was prepared by filtering, washing, drying, and screening to remove iron.

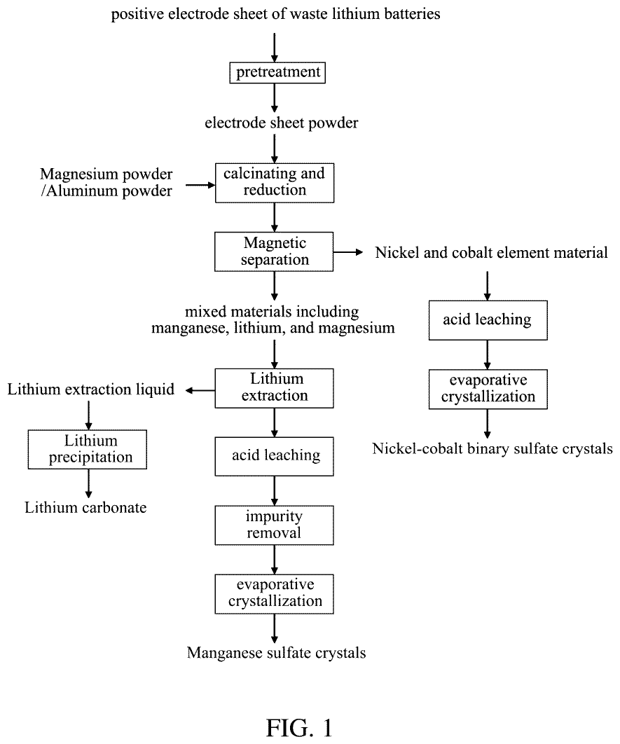

A schematic flowchart of this example is shown in FIG. 1, and some unnecessary steps are not shown in detail.

### Example 2

This example provided a recovery method of valuable metal in positive electrode sheet of a lithium battery, and the specific process was as follows:

A1. Pretreatment: A waste ternary positive electrode sheet of a lithium battery (provided by Guangdong Brunp Recycling Technology Co., Ltd., containing Ni 36.5%, Co 11.3%, Mn 12.4%, and Li 7.1% in terms of mass percentage) was subjected to shredding, sorting and screening processes in sequence to obtain electrode sheet powder.

A2. Deep reduction of aluminum powder:
A21. The electrode sheet powder obtained in step A1 was mixed uniformly with aluminum powder at a mass ratio of 1:1.2; and
A22. The powder obtained in step A21 was placed in a tube furnace under a nitrogen atmosphere, heated at a heating rate of 5° C./min, from 25° C. to 600° C., then calcinated for 2 h and cooled.

A3. Magnetic separation: The electrode sheet powder obtained in step A2 was subjected to magnetic separation with a magnetic separator under the condition of a magnetic field strength of 30 T to obtain magnetic powder of elementary substances of nickel and cobalt (magnetic components) and non-magnetic mixed material including manganese, lithium (compound), aluminum (compound+elementary substance) and the like (non-magnetic components).

A4. Preparation of nickel-cobalt binary sulfate crystal:
A41. The magnetic components obtained in step A3 were added with pure water at a solid-liquid ratio of 1 g:3 mL for slurrying;
A42. The slurry obtained in step A41 was added with sulfuric acid for acid dissolution, wherein a molar ratio of sulfuric acid to the magnetic components was 1.5:1;
A43. After the magnetic components were completely dissolved, a sodium carbonate solution was added to the obtained nickel-cobalt solution to adjust the pH to 5.5; and
A44. The pH-adjusted nickel-cobalt solution was evaporated to concentrate the total concentration of nickel and cobalt to 220 g/L, and then, the concentrated solution was transferred to a crystallization kettle for cooling crystallization at 30° C. for 5 h, followed by centrifugation treatment, to obtain high-purity nickel-cobalt binary sulfate crystal,
wherein, the total recovery rate of nickel and cobalt was 97%, and the calculation method thereof referred to Example 1.

A5. Selective lithium extraction:
A51. The non-magnetic components obtained in step A3 were added with pure water at a solid-liquid ratio of 1 g:3 mL for slurrying;
A52. Under stirring, a sulfuric acid solution with a concentration of 2 wt % was injected with peristaltic pump at flow rate of 2.5 mL/min, to adjust the pH of the slurry obtained in step A51 to 8.0, after that, stirring was continued for 30 min and filtration was performed to obtain filter residue and an extract by means of water;
A53. The filter residue obtained in step A52 was washed with pure water, and a washing solution obtained was added to the extract by means of water,
the specific operation of washing was as follows: firstly, pure water was added to the filter residue at a solid-liquid ratio of 1 g:3 mL for slurrying, and stirred for 40 min, then, the filter residue and the washing solution were obtained by filtration, and then the obtained filter residue was rinsed with pure water twice; and
A54. Sodium carbonate was added to the extract by means of water obtained in step A53 to prepare battery-grade lithium carbonate.

A6. Preparation of manganese sulfate crystal:
A61. The filter residue obtained in step A53 was added with pure water at a solid-liquid ratio of 1 g:3 mL for slurrying;
A62. Under stirring, the slurry obtained in step A61 was added with sulfuric acid to adjust the pH to 1.0, and reacted at 60° C. for 4 h;
A63. The slurry obtained in step A62 was added with a sodium carbonate solution to adjust the pH of the slurry to 5.5, and filtration was performed to obtain aluminum residue and a manganese sulfate solution,
the aluminum residue was washed twice with pure water, and the washing solution was combined into the manganese sulfate solution; and
A64. The manganese sulfate solution obtained in step A63 was subjected to evaporative crystallization to prepare battery-grade manganese sulfate crystal.

A7. Preparation of elementary substance of aluminum from aluminum residue:
A71. The aluminum residue obtained in step A63 was added with pure water for slurrying with a solid-liquid ratio of 1 g:3 mL;
A72. The slurry obtained in step A71 was added with 20% sodium hydroxide solution and stirred at 95° C. for 40 min, with the pH at end point of the reaction adjusted to 13, and filtration was performed;
A73. The solution obtained in step A72 was added with sulfuric acid to adjust pH to 6.5, and then filtered to obtain filter residue;
A74. The filter residue obtained in step A73 was calcinated at 600° C. for 2 h in a tube furnace under an air atmosphere to obtain alumina; and
A75. The alumina was electrolyzed at a temperature of 950° C. with direct current by using the alumina obtained in step A74 as a solute, cryolite as a solvent, graphite as anode, and aluminum liquid as cathode to obtain elementary substance of aluminum.

A8. Precursor synthesis:

The nickel-cobalt binary sulfate crystal obtained in step A4 and the manganese sulfate crystal obtained in step A6 were dissolved with pure water, and a molar ratio of nickel, to cobalt, and to manganese in the system was adjusted to 6:2:2. Then, ammonia water and sodium hydroxide were added to adjust the pH of the solution to 11.0, and the synthesis reaction temperature was controlled to 65° C. After the reaction was complete, a precursor material of NCM 6:2:2 type was prepared by filtering, washing, drying, and screening to remove iron.

### Example 3

This example provided a recovery method of valuable metal in positive electrode sheet of a lithium battery, and the specific process was as follows:

A1. Pretreatment: A waste ternary positive electrode sheet of a lithium battery (from Guangdong Brunp Recycling Technology Co., Ltd., containing Ni 31.7%, Co 11.4%, Mn 16.5%, and Li 7.1% in terms of mass percentage) was subjected to shredding, sorting and screening processes in sequence to obtain electrode sheet powder.

A2. Deep reduction of aluminum powder:
A21. The electrode sheet powder obtained in step A1 was mixed uniformly with aluminum powder at a mass ratio of 1:1; and
A22. The powder obtained in step A21 was placed in a tube furnace under a nitrogen atmosphere, heated at a heating rate of 2° C./min, from 25° C. to 500° C., then calcinated for 3 h and cooled.

A3. Magnetic separation: The electrode sheet powder obtained in step A2 was subjected to magnetic separation with a magnetic separator under the condition of a magnetic field strength of 20 T to obtain magnetic powder of elementary substances of nickel and cobalt (magnetic components) and non-magnetic mixed material including manganese, lithium (compound), aluminum (compound+elementary substance) and the like (non-magnetic components).

A4. Preparation of nickel-cobalt binary sulfate crystal:
A41. The magnetic components obtained in step A3 were added with pure water at a solid-liquid ratio of 1 g:3 mL for slurrying;
A42. The slurry obtained in step A41 was added with sulfuric acid for acid dissolution, wherein a molar ratio of sulfuric acid to the magnetic components was 1.2:1;
A43. After the magnetic components were completely dissolved, a sodium carbonate solution was added to the obtained nickel-cobalt solution to adjust the pH to 5.0; and
A44. The pH-adjusted nickel-cobalt solution was evaporated to concentrate the total concentration of nickel and cobalt to 180 g/L, and then, the concentrated solution was transferred to a crystallization kettle for cooling crystallization at 45° C. for 12 h, followed by centrifugation treatment, to obtain high-purity nickel-cobalt binary sulfate crystal.

A5. Selective lithium extraction:
A51. The non-magnetic components obtained in step A3 were added with pure water at a solid-liquid ratio of 1 g:3 mL for slurrying;
A52. Under stirring, a sulfuric acid solution with a concentration of 4 wt % was injected with peristaltic pump at flow rate of 1.5 mL/min, to adjust the pH of the slurry obtained in step A51 to 7.0, after that, stirring was continued for 30 min and filtration was performed to obtain filter residue and an extract by means of water;
A53. The filter residue obtained in step A52 was washed with pure water, and a washing solution obtained was added to the extract by means of water,
the specific operation of washing was as follows: firstly, pure water was added to the filter residue at a solid-liquid ratio of 1 g:3 mL for slurrying, and stirred for 30 min, then, the filter residue and the washing solution were obtained by filtration, and then the obtained filter residue was rinsed with pure water twice; and
A54. Sodium carbonate was added to the extract by means of water obtained in step A53 to prepare battery-grade lithium carbonate.

A6. Preparation of manganese sulfate crystal:
A61. The filter residue obtained in step A53 was added with pure water at a solid-liquid ratio of 1 g:3 mL for slurrying;
A62. Under stirring, the slurry obtained in step A61 was added with sulfuric acid to adjust the pH to 1.0, and reacted at 70° C. for 3 h;
A63. The slurry obtained in step A62 was added with a sodium carbonate solution to adjust the pH of the slurry to 5.5, and filtration was performed to obtain aluminum residue and a manganese sulfate solution,
the aluminum residue was washed twice with pure water, and the washing solution was combined into the manganese sulfate solution; and
A64. The manganese sulfate solution obtained in step A63 was subjected to evaporative crystallization to prepare battery-grade manganese sulfate crystal.

A7. Preparation of elementary substance of aluminum from aluminum residue:
A71. The aluminum residue obtained in step A63 was added with pure water for slurrying;
A72. The slurry obtained in step A71 was added with 25 wt % of sodium hydroxide solution and stirred at 85° C. for 50 min, with the pH at end point of the reaction adjusted to 14, and filtration was performed;
A73. The solution obtained in step A72 was added with sulfuric acid to adjust pH to 7.0, and then filtered to obtain filter residue;
A74. The filter residue obtained in step A73 was calcinated at 500° C. for 3 h in a tube furnace under an air atmosphere to obtain alumina; and
A75. The alumina was electrolyzed at a temperature of 950° C. with direct current by using the alumina obtained in step A74 as a solute, cryolite as a solvent, graphite as anode, and aluminum liquid as cathode to obtain elementary substance of aluminum.

A8. Precursor synthesis:
The nickel-cobalt binary sulfate crystal obtained in step A4 and the manganese sulfate crystal obtained in step A6 were dissolved with pure water, and a molar ratio of nickel, to cobalt, and to manganese in the system was adjusted to 8:1:1. Then, ammonia water and sodium hydroxide were added to adjust the pH of the solution, and the synthesis reaction temperature was controlled. After the reaction was complete, a precursor material of NCM 8:1:1 type was prepared by filtering, washing, drying, and screening to remove iron.

### Example 4

This example provided a recovery method of valuable metal in positive electrode sheet of a lithium battery, and the specific process was as follows:

B1. Pretreatment: A waste ternary positive electrode sheet of a lithium battery (from Guangdong Brunp Recycling Technology Co., Ltd., containing Ni 47.3%, Co 6.2%, Mn 5.9%, and Li 7.2% in terms of mass percentage) was subjected to shredding, sorting and screening processes to obtain electrode sheet powder.

B2. Deep reduction of magnesium powder:
B21. The electrode sheet powder obtained in step B1 was mixed with magnesium powder at a mass ratio of 1:0.6; and
B22. The mixed powder obtained in step B21 was calcinated in a tube furnace under nitrogen atmosphere at a heating rate of 1.5° C./min, from 25° C. to 450° C., then calcinated for 4 h and cooled.

B3. The powder obtained in step B22 was subjected to magnetic separation with a magnetic separator under the condition of a magnetic field strength of 15 T to obtain magnetic powder of elementary substances of nickel and cobalt (magnetic components) and non-magnetic mixed material including manganese, lithium, magnesium and the like (non-magnetic components).

B4. Preparation of nickel-cobalt binary sulfate crystal:
B41. The magnetic components obtained in step B3 were mixed with pure water at a solid-liquid ratio of 1 g:3 mL for slurrying;
B42. The slurry obtained in step B41 was added with sulfuric acid at a molar ratio of the magnetic components to sulfuric acid of 1:1.1, and after the magnetic components were completely digested, the obtained nickel-cobalt solution was added with a sodium carbonate solution to adjust the pH to 5.0;
B43. The nickel-cobalt solution obtained in step B42 was evaporated to concentrate the total concentration of nickel and cobalt to 180 g/L; and
B44. The solution obtained in step B43 was transferred to a crystallization kettle for cooling crystallization at 50° C. for 12 h, followed by centrifugation treatment, to obtain high-purity nickel-cobalt binary sulfate crystal, which was used as raw material for synthesizing ternary precursor.

B5. Selective lithium extraction:
B51. The non-magnetic components obtained in step B3 were added with pure water at a solid-liquid ratio of 1 g:3 mL for slurrying;
B52. Under stirring, an aluminum sulfate solution with a concentration of 15 wt % was injected with peristaltic pump at flow rate of 2 mL/min, to adjust the pH of the slurry at end point to 6.0, after that, stirring was continued for 30 min and solid-liquid separation was performed to obtain a sediment and a filtrate;
B53. The sediment obtained in step B52 was continued to be added with pure water at a solid-liquid ratio of 1 g:3 mL for slurrying and stirred for 30 min, solid-liquid separation was then performed to obtain a sediment and a filtrate, and the sediment was rinsed twice with pure water; and
B54. The filtrate obtained in this step was combined, and soda was added to prepare lithium carbonate.

B6. Preparation of manganese sulfate crystal:
B61. The sediment obtained in step B53 was added with water at a solid-liquid ratio of 1 g:3 mL for slurrying;
B62. Under stirring, the slurry obtained in step B61 was added with sulfuric acid to adjust the pH to 1.0, and reacted at 80° C. for 2 h;
B63. The slurry obtained in step B62 was added with sodium carbonate to adjust the pH of the slurry to 5.0 to remove aluminum, and solid-liquid separation was performed;
B64. The filtrate obtained in step B63 was added with sodium fluoride to remove magnesium, wherein the amount of substance of sodium fluoride was 3 times of the amount of substance of magnesium, and filtration was performed to obtain magnesium fluoride residue and a manganese sulfate solution,
the magnesium fluoride residue was washed twice with pure water, and the washing solution was combined into the manganese sulfate solution; and
B65. The manganese sulfate solution obtained in step B64 was subjected to defluorination (by adding aluminum sulfate for defluorination, Al³⁺+6F⁻+3Na⁺→Na₃AlF₆↓, the addition amount thereof was 1.3 times the theoretical amount of the reaction involving fluorine, and the pH at the reaction end point was adjusted with a sodium carbonate solution to 5.5), and then, evaporative crystallization was performed to prepare battery-grade manganese sulfate crystal;

B7. Precursor synthesis:
The nickel-cobalt binary sulfate crystal obtained in step B4 and the manganese sulfate crystal obtained in step B6 were dissolved with pure water, and a molar ratio of nickel, to cobalt, and to manganese in the system was adjusted to 5:2:3. Then, ammonia water and sodium hydroxide were added to adjust the pH of the solution to 11.0, and the synthesis reaction temperature was controlled. After the reaction was complete, a precursor material of NCM 5:2:3 type was prepared by filtering, washing, drying, and screening to remove iron.

### Example 5

This example provided a recovery method of valuable metal in positive electrode sheet of a lithium battery, and the specific process was as follows:

B1. Pretreatment: A waste ternary positive electrode sheet of a lithium battery (from Guangdong Brunp Recycling Technology Co., Ltd., containing Ni 47.3%, Co 6.2%, Mn 5.9%, and Li 7.2% in terms of mass percentage) was subjected to shredding, sorting and screening processes to obtain electrode sheet powder.

B2. Deep reduction of magnesium powder:
B21. The electrode sheet powder obtained in step B1 was mixed with magnesium powder at a mass ratio of 1:1.0; and
B22. The mixed powder obtained in step B21 was calcinated in a tube furnace under nitrogen atmosphere at a heating rate of 5° C./min, from 25° C. to 450° C., then calcinated for 2.5 h and cooled.

B3. The powder obtained in step B22 was subjected to magnetic separation with a magnetic separator under the condition of a magnetic field strength of 30 T to obtain magnetic powder of elementary substances of nickel and cobalt (magnetic components) and non-magnetic mixed material including manganese, lithium, magnesium and the like (non-magnetic components).

B4. Preparation of nickel-cobalt binary sulfate crystal:
B41. The magnetic components obtained in step B3 were mixed with pure water at a solid-liquid ratio of 1 g:3 mL for slurrying;
B42. The slurry obtained in step B41 was added with sulfuric acid at a molar ratio of the magnetic components to sulfuric acid of 1:1.3, and after the magnetic components were completely digested, the obtained nickel-cobalt solution was added with a sodium carbonate solution to adjust the pH to 5.0;
B43. The nickel-cobalt solution obtained in step B42 was evaporated to concentrate the total concentration of nickel and cobalt to 200 g/L; and
B44. The solution obtained in step B43 was transferred to a crystallization kettle for cooling crystallization at 30° C. for 6 h, followed by centrifugation treatment, to obtain high-purity nickel-cobalt binary sulfate crystal, which was used as raw material for synthesizing ternary precursor.

B5. Selective lithium extraction:
B51. The non-magnetic components obtained in step B3 were added with pure water at a solid-liquid ratio of 1 g:3 mL for slurrying;
B52. Under stirring, an aluminum chloride solution with a concentration of 10 wt % was injected with peristaltic pump at flow rate of 5 mL/min, to adjust the pH of the slurry at end point to 8.0, after that, stirring was continued for 30 min and solid-liquid separation was performed to obtain a sediment and a filtrate;
B53. The sediment obtained in step B52 was continued to be added with pure water at a solid-liquid ratio of 1 g:3 mL for slurrying and stirred for 40 min, solid-liquid separation was then performed to obtain a sediment and a filtrate, and the sediment was rinsed twice with pure water; and
B54. The filtrate obtained in this step was combined, and soda was added to prepare lithium carbonate.

B6. Preparation of manganese sulfate crystal:
B61. The sediment obtained in step B53 was added with water at a solid-liquid ratio of 1 g:3 mL for slurrying;
B62. Under stirring, the slurry obtained in step B61 was added with sulfuric acid to adjust the pH to 1.0, and reacted at 60° C. for 4 h;
B63. The slurry obtained in step B62 was added with sodium carbonate to adjust the pH of the slurry to 5.0 to remove aluminum, and solid-liquid separation was performed;
B64. The filtrate obtained in step B63 was added with sodium fluoride to remove magnesium, wherein the amount of substance of sodium fluoride was 3 times of the amount of substance of magnesium, and filtration was performed to obtain magnesium fluoride residue and a manganese sulfate solution,
the magnesium fluoride residue was washed twice with pure water, and the washing solution was combined into the manganese sulfate solution; and
B65. The manganese sulfate solution obtained in step B64 was subjected to defluorination (by adding aluminum sulfate for defluorination, Al³⁺+6F⁻+3Na⁺→Na₃AlF₆↓, the addition amount thereof was 1.3 times the theoretical amount of the reaction involving fluorine, and the pH at the reaction end point was adjusted with a sodium carbonate solution to 5.5), and then, evaporative crystallization was performed to prepare battery-grade manganese sulfate crystal.

B7. Precursor synthesis:
The nickel-cobalt binary sulfate crystal obtained in step B4 and the manganese sulfate crystal obtained in step B6 were dissolved with pure water, and a molar ratio of nickel, to cobalt, and to manganese in the system was adjusted to 6:2:2. Then, ammonia water and sodium hydroxide were added to adjust the pH of the solution to 11.0, and the synthesis reaction temperature was controlled to 65° C. After the reaction was complete, a precursor material of NCM 6:2:2 type was prepared by filtering, washing, drying, and screening to remove iron.

### Example 6

This example provided a recovery method of valuable metal in positive electrode sheet of a lithium battery, and the specific process was as follows:

B1. Pretreatment: A waste ternary positive electrode sheet of a lithium battery (from Guangdong Brunp Recycling Technology Co., Ltd., containing Ni 47.3%, Co 6.2%, Mn 5.9%, and Li 7.2% in terms of mass percentage) was subjected to shredding, sorting and screening processes to obtain electrode sheet powder.

B2. Deep reduction of magnesium powder:
B21. The electrode sheet powder obtained in step B1 and magnesium powder were mixed at a mass ratio of 1:0.8; and
B22. The mixed powder obtained in step B21 was calcinated in a tube furnace under nitrogen atmosphere at a heating rate of 2° C./min, from 25° C. to 400° C., then calcinated for 3 h and cooled.

B3. The powder obtained in step B22 was subjected to magnetic separation with a magnetic separator under the condition of a magnetic field strength of 20 T to obtain magnetic powder of elementary substances of nickel and cobalt (magnetic components) and non-magnetic mixed material including manganese, lithium, magnesium and the like (non-magnetic components).

B4. Preparation of nickel-cobalt binary sulfate crystal:
B41. The magnetic components obtained in step B3 were mixed with pure water at a solid-liquid ratio of 1 g:3 mL for slurrying;
B42. The slurry obtained in step B41 was added with sulfuric acid at a molar ratio of the magnetic components to sulfuric acid of 1:1.2, and after the magnetic components were completely digested, the obtained nickel-cobalt solution was added with a sodium carbonate solution to adjust the pH to 5.0;
B43. The nickel-cobalt solution obtained in step B42 was evaporated to concentrate the total concentration of nickel and cobalt to 160 g/L; and
B44. The solution obtained in step B43 was transferred to a crystallization kettle for cooling crystallization at 45° C. for 15 h, followed by centrifugation treatment, to obtain high-purity nickel-cobalt binary sulfate crystal, which was used as raw material for synthesizing ternary precursor.

B5. Selective lithium extraction:
B51. The non-magnetic components obtained in step B3 were added with pure water at a solid-liquid ratio of 1 g:3 mL for slurrying;
B52. Under stirring, a ferric chloride solution with a concentration of 10 wt % was injected with peristaltic pump at flow rate of 2.5 mL/min, to adjust the pH of the slurry at end point to 7.0, after that, stirring was continued for 30 min and solid-liquid separation was performed to obtain a sediment and a filtrate;
B53. The sediment obtained in step B52 was continued to be added with pure water at a solid-liquid ratio of 1 g:3 mL for slurrying and stirred for 40 min, solid-liquid separation was then performed to obtain a sediment and a filtrate, and the sediment was rinsed twice with pure water; and
B54. The filtrate obtained in this step was combined, and soda was added to prepare lithium carbonate.

B6. Preparation of manganese sulfate crystal:
B61. The sediment obtained in step B53 was added with water at a solid-liquid ratio of 1 g:3 mL for slurrying;
B62. Under stirring, the slurry obtained in step B61 was added with sulfuric acid to adjust the pH to 1.0, and reacted at 70° C. for 3 h;
B63. The slurry obtained in step B62 was added with sodium carbonate to adjust the pH of the slurry to 5.0 to remove aluminum, and solid-liquid separation was performed;
B64. The filtrate obtained in step B63 was added with sodium fluoride to remove magnesium, wherein the amount of substance of sodium fluoride was 3 times of that of magnesium, and filtration was performed to obtain magnesium fluoride residue and a manganese sulfate solution;
the magnesium fluoride residue was washed twice with pure water, and the washing solution was combined into the manganese sulfate solution; and

B65. The manganese sulfate solution obtained in step B64 was subjected to defluorination (by adding aluminum sulfate for defluorination, Al³⁺+6F⁻+3Na⁺→Na₃AlF₆↓, the addition amount was 1.3 times the theoretical amount of the reaction involving fluorine, and the pH at the reaction end point was adjusted with a sodium carbonate solution to 5.5), and then, evaporative crystallization was performed to prepare battery-grade manganese sulfate crystal.

B7. Precursor synthesis:
The nickel-cobalt binary sulfate crystal obtained in step B4 and the manganese sulfate crystal obtained in step B6 were dissolved with pure water, and a molar ratio of nickel, to cobalt, and to manganese in the system was adjusted to 8:1:1. Then, ammonia water and sodium hydroxide were added to adjust the pH of the solution to 11.0, and the synthesis reaction temperature was controlled to 65° C. After the reaction was complete, a precursor material of NCM 8:1:1 type was prepared by filtering, washing, drying, and screening to remove iron.

### Comparative Example 1

This comparative example provided a traditional recovery method of valuable metal in positive electrode sheet of a lithium battery, and the specific process was as follows:

T1. A waste ternary positive electrode sheet (from Guangdong Brunp Recycling Technology Co., Ltd., containing Ni 47.3%, Co 6.2%, Mn 5.9%, and Li 7.2% in terms of mass percentage) was subjected to shredding, sorting and screening processes to obtain electrode sheet powder.

T2. The electrode sheet powder obtained in step T1 was added with pure water at a solid-liquid ratio of 1 g:5 mL for slurrying, and then added with sulfuric acid and hydrogen peroxide for leaching, wherein the amount of sulfuric acid added was 2.0 times the amount of substance of nickel, cobalt and manganese in the electrode sheet powder, and the amount of hydrogen peroxide added was 1.0 time the amount of substance of nickel, cobalt, and manganese in the electrode sheet powder. Then, sodium carbonate was added to adjust the pH to 5.0 to remove aluminum, and solid-liquid separation was performed to obtain a solution containing nickel, cobalt, manganese, and lithium.

T3. First, the manganese in the solution of nickel, cobalt, manganese, and lithium obtained in step T2 was extracted into an organic phase with P204 extractant, and a raffinate was a solution of nickel, cobalt and lithium. An organic phase was back-extracted with sulfuric acid to obtain a manganese sulfate solution, which was then subjected to evaporative crystallization to prepare manganese sulfate crystal.

T4. The raffinate obtained in step T3 was extracted with P507 extractant to extract nickel and cobalt into an organic phase, and a raffinate was a solution containing lithium; the organic phase was back-extracted with sulfuric acid to obtain a nickel-cobalt sulfate solution, which was then subjected to evaporative crystallization to prepare the nickel-cobalt binary sulfate crystal.

T5. The raffinate obtained in step T4 was added with an alkali to prepare lithium carbonate product.

T6. The nickel-cobalt binary sulfate crystal obtained in step T4 and the manganese sulfate crystal in step T3 were dissolved with pure water, and a molar ratio of nickel, to cobalt, and to manganese in the system was adjusted to 5:2:3. Then, ammonia water and sodium hydroxide were added to adjust the pH of the solution, and the synthesis reaction temperature was controlled. After the reaction was complete, a precursor material of NCM 5:2:3 type was prepared by filtering, washing, drying, and screening to remove iron.

### Test Example

In the first aspect of this test example, the components of the nickel-cobalt binary sulfate crystal obtained in Examples 1˜6 and Comparative Example 1 (Steps A4, and B4 in Examples, and Step T4 in Comparative Example) were tested, and the test method was ICP-OES. Test results are shown in Table 1:

TABLE 1
Components of the nickel-cobalt binary sulfate crystal
obtained in Examples 1~6 and Comparative Example 1

| | | | Impurity content/ppm | | | | | | | | | | | |
|---|---|---|---|---|---|---|---|---|---|---|---|---|---|---|
| Product | Ni/% | Co/% | Mn | Li | Ca | Mg | Cu | Fe | Zn | Al | Na | Pb | Cr | Cd |
| Example 1 | 18.3 | 4.5 | 2 | 3 | 3 | 2 | 1 | 1 | <1 | 2 | 50 | <1 | <1 | <1 |
| Example 2 | 17.6 | 5.1 | 2 | 2 | 3 | 2 | 1 | 1 | <1 | 2 | 61 | <1 | <1 | <1 |
| Example 3 | 20.2 | 2.5 | 2 | 3 | 3 | 2 | 1 | 1 | <1 | 3 | 42 | <1 | <1 | <1 |
| Example 4 | 17.5 | 5.1 | 3 | 2 | 2 | 3 | 1 | 1 | <1 | 1 | 56 | <1 | <1 | <1 |
| Example 5 | 18.6 | 4.2 | 2 | 2 | 3 | 2 | 1 | 1 | <1 | 1 | 49 | <1 | <1 | <1 |
| Example 6 | 18.2 | 4.5 | 3 | 2 | 2 | 2 | 1 | 1 | <1 | 1 | 53 | <1 | <1 | <1 |
| Comparative Example 1 | 19.4 | 3.2 | 420 | 185 | 3 | 3 | 1 | 1 | <1 | 2 | 71 | <1 | <1 | <1 |

As can be seen from Table 1, the contents of impurities Mn, Li, Ca, Mg, Cu, and Fe in the nickel-cobalt binary sulfate crystal prepared in Examples 1˜6 were less than 3 ppm, and the contents of Zn, Pb, Cr, and Cd were less than 1 ppm, indicating that nickel-cobalt binary sulfate crystal were of high purity. However, the contents of Mn and Li in the nickel-cobalt binary sulfate crystal prepared in Comparative Example 1 were as high as 420 ppm and 185 ppm, respectively, and the purity thereof was significantly lower than that of the nickel-cobalt binary sulfate crystal prepared in Examples 1˜6.

In the second aspect of this test example, the components of the manganese sulfate crystal obtained in Examples 1˜6 and Comparative Example 1 (Step A6 in Examples, and Step T3 in Comparative Example) were tested, and the specific test method was ICP-OES. The specific results are shown in Table 2:

TABLE 2
Components of the manganese sulfate crystal obtained
in Examples 1~6 and Comparative Example 1

| | | Impurity content/ppm | | | | | | | | | | | | |
|---|---|---|---|---|---|---|---|---|---|---|---|---|---|---|
| Product | Mn/% | Ni | Co | Li | Ca | Mg | Cu | Fe | Zn | Al | Na | Pb | Cr | Cd |
| Example 1 | 32.2 | 2 | 3 | 3 | 3 | 2 | 1 | 1 | <1 | 2 | 46 | <1 | <1 | <1 |
| Example 2 | 32.1 | 2 | 2 | 2 | 2 | 3 | 1 | 1 | <1 | 2 | 57 | <1 | <1 | <1 |
| Example 3 | 32.3 | 2 | 3 | 3 | 3 | 2 | 1 | 1 | <1 | 3 | 51 | <1 | <1 | <1 |
| Example 4 | 32.4 | 3 | 2 | 2 | 2 | 3 | 1 | 1 | <1 | 1 | 53 | <1 | <1 | <1 |
| Example 5 | 32.2 | 2 | 2 | 3 | 3 | 2 | 1 | 1 | <1 | 1 | 56 | <1 | <1 | <1 |
| Example 6 | 32.5 | 3 | 3 | 2 | 3 | 3 | 1 | 1 | <1 | 1 | 61 | <1 | <1 | <1 |
| Comparative Example | 31.5 | 2285 | 3469 | 260 | 3 | 3 | 1 | 1 | <1 | 2 | 68 | <1 | <1 | <1 |

As can be seen from Table 2, the contents of impurities nickel, cobalt and lithium in the manganese sulfate crystal prepared in Examples 1˜6 were significantly lower than that of Comparative Example 1, indicating that the preparation methods of Examples 1˜6 were significantly superior to that of Comparative Example 1. This is because when P204 was used to extract manganese, a part of nickel and cobalt would also be extracted into the organic phase, resulting in high contents of nickel and cobalt in the manganese sulfate solution after back-extraction, thus affecting the quality of manganese sulfate product after evaporative crystallization.

In the third aspect of this test example, the components of the lithium carbonate obtained in Examples 1˜6 and Comparative Example 1 (Example Step A5, Comparative Example Step T5) were tested, and the specific test method was ICP-OES. The specific results are shown in Table 3:

TABLE 3
Components of the lithium carbonate obtained
in Examples 1~3 and Comparative Example 1

| | | Impurity Content/ppm | | | | | | | | | | | | |
|---|---|---|---|---|---|---|---|---|---|---|---|---|---|---|
| Product | Li/% | Ni | Co | Mn | Ca | Mg | Cu | Fe | Zn | Al | Na | Pb | Cr | Cd |
| Example 1 | 18.4 | 2 | 3 | 2 | 2 | 3 | 1 | 1 | <1 | 2 | 36 | <1 | <1 | <1 |
| Example 2 | 18.3 | 2 | 2 | 3 | 2 | 3 | 1 | 1 | <1 | 2 | 41 | <1 | <1 | <1 |
| Example 3 | 18.6 | 2 | 3 | 2 | 3 | 2 | 1 | 1 | <1 | 3 | 35 | <1 | <1 | <1 |
| Example 4 | 18.5 | 3 | 2 | 3 | 2 | 3 | 1 | 1 | <1 | 2 | 38 | <1 | <1 | <1 |
| Example 5 | 18.3 | 2 | 3 | 2 | 2 | 2 | 1 | 1 | <1 | 2 | 42 | <1 | <1 | <1 |
| Example 6 | 18.4 | 2 | 2 | 2 | 2 | 3 | 1 | 1 | <1 | 3 | 39 | <1 | <1 | <1 |
| Comparative | 18.5 | 2 | 2 | 2 | 3 | 3 | 1 | 1 | <1 | 2 | 52 | <1 | <1 | <1 |
| Example 1 | | | | | | | | | | | | | | |

As can be seen from Table 3, the components of the lithium carbonate obtained in Examples 1˜3 were comparable with those of and Comparative Example 1.

To sum up, with regard to the recovery method provided by the present disclosure, impurity removal is not required, and nickel-cobalt binary sulfate product can be prepared through simple crystallization. For the non-magnetic material such as lithium and manganese, lithium is selectively extracted by adding water for slurrying and then adjusting pH. After solid-liquid separation, lithium carbonate is prepared from the solution by adding soda, and the manganese sulfate product is prepared from a residue after dissolving the residue in an acid, removing impurities and then crystallizing. The whole process is performed only through simple chemical impurity removal and evaporative crystallization.

In Comparative Example 1, the nickel, cobalt, manganese, and lithium in the electrode sheet powder must be dissolved by adding with an acid and a reductant. First, chemical impurity removal is performed. Then, manganese is extracted into the organic phase with P204 extractant, and the raffinate is extracted with P507 extractant to extract nickel and cobalt into the organic phase. The raffinate after P507 extraction was degreased and then added with soda to prepare lithium carbonate. The manganese sulfate solution obtained after back-extraction of the organic phase obtained after P204 extraction with sulfuric acid is degreased, and subjected to evaporative crystallization to prepare manganese sulfate. The nickel-cobalt sulfate solution obtained after back-extraction of the organic phase obtained after P507 extraction with sulfuric acid is degreased, and subjected to evaporative crystallization to prepare nickel-cobalt binary sulfate product. In the whole process, the extractant is used for many times, and each corresponding extraction needs to go through the steps of saponification, mixing, clarification, washing, back-extraction, and degreasing.

Therefore, on the whole, comparative example is more complicated than examples, and the purity of the obtained product is lower.

Examples of the present disclosure have been described in detail above in conjunction with the drawings. However, the present disclosure is not limited to the above-mentioned examples, and various modifications can be made without departing from the purpose of the present disclosure within the scope of knowledge possessed by those of ordinary skill in the art. In addition, in the case of no conflict, examples of the present disclosure and the features in examples may be combined with each other.

1. A method for recovering valuable metal in positive electrode sheet of a lithium battery, comprising steps of:
S1, mixing a material of the positive electrode sheet with a reducing metal to obtain a mixture, and calcinating the mixture, wherein the calcinating is carried out under a protective atmosphere;
S2, performing magnetic separation on a material obtained in step S1 to obtain a magnetic component and a non-magnetic component;
S3, dissolving the magnetic component in an acid, concentrating an obtained leachate, and performing crystallization to obtain a metal salt A; and
S4, leaching the non-magnetic component with water to obtain a sediment and a leachate obtained by water leaching;
adding a carbonate into the leachate obtained by water leaching to obtain lithium carbonate; and
dissolving the sediment in an acid, purifying, and then performing crystallization to obtain a metal salt B from an obtained solution after the dissolving.

2. The recovery method according to claim 1, wherein in step S1, the material of the positive electrode sheet comprises at least one of lithium nickel-cobalt manganate, lithium nickelate, lithium cobaltate, lithium manganate and lithium nickel-cobalt aluminate.

3. The recovery method according to claim 1, wherein in step S1, the reducing metal comprises at least one of magnesium and aluminum; and a mass ratio of the reducing metal to the material of the positive electrode sheet is 0.4˜1.2:1.

4. The recovery method according to claim 1, wherein in step S1, a temperature of the calcinating is 300˜600° C.; preferably, a duration of the calcinating is 2˜5 h.

5. The recovery method according to claim 1, wherein in step S2, a magnetic field strength of the magnetic separation is 10˜30 T.

6. The recovery method according to claim 1, wherein step S3, before dissolving in the acid, further involves slurrying the magnetic component by mixing it with water; preferably, in step S3, with regard to dissolving in the acid, a molar ratio of hydrogen ions in the acid to the magnetic component is 2.2˜3:1; preferably, pH of the leachate is 4˜6.

7. The recovery method according to claim 1, wherein in step S3, after the concentrating, a total concentration of the metal in the leachate is 120˜220 g/L; preferably, in step S3, the crystallization is at least one of cooling crystallization and evaporative crystallization.

8. The recovery method according to claim 1, wherein in step S4, with regard to leaching with water, a ratio of the non-magnetic component to water is 1 g:3˜5 mL; preferably, pH for leaching with water is 6.0˜8.0.

9. The recovery method according to claim 1, wherein in step S4, with regard to dissolving in the acid, pH is 1.0˜1.5; preferably, in step S4, a temperature of the dissolving in the acid is 60˜80° C.; preferably, in step S4, a duration of the dissolving in the acid is 2˜4 h.

10. The recovery method according to claim 1, wherein the recovery method further comprises preparing a precursor of a positive electrode material by using the metal salt A and the metal salt B.

11. The recovery method according to claim 2, wherein the recovery method further comprises preparing a precursor of a positive electrode material by using the metal salt A and the metal salt B.

12. The recovery method according to claim 3, wherein the recovery method further comprises preparing a precursor of a positive electrode material by using the metal salt A and the metal salt B.

13. The recovery method according to claim 4, wherein the recovery method further comprises preparing a precursor of a positive electrode material by using the metal salt A and the metal salt B.

14. The recovery method according to claim 5, wherein the recovery method further comprises preparing a precursor of a positive electrode material by using the metal salt A and the metal salt B.

15. The recovery method according to claim 6, wherein the recovery method further comprises preparing a precursor of a positive electrode material by using the metal salt A and the metal salt B.

16. The recovery method according to claim 7, wherein the recovery method further comprises preparing a precursor of a positive electrode material by using the metal salt A and the metal salt B.

17. The recovery method according to claim 8, wherein the recovery method further comprises preparing a precursor of a positive electrode material by using the metal salt A and the metal salt B.

18. The recovery method according to claim 9, wherein the recovery method further comprises preparing a precursor of a positive electrode material by using the metal salt A and the metal salt B.
